(19) United States
(12) Patent Application Publication
(10) Pub. No.: US 2006/0098217 A1
(43) Pub. Date: May 11, 2006

(54) Simulation of profile gives prediction of specific colors

(75) Inventors: Chung-I Chang, San Chung (TW); Shih-Chang Chang, San Chung (TW); Chia-Pin Chueh, San Chung (TW)

Correspondence Address: Printing Technology Research Institute, P.O. Box 166-13, Taipei, 115, TW

(73) Assignee: Printing Technology Research Institute

(21) Appl. No.: 11/042,839

(22) Filed: Jan. 19, 2005

(30) Foreign Application Priority Data
Nov. 10, 2004 (TW) 093134340

(51) Int. Cl. G03F 3/08; G06F 15/00

(52) U.S. Cl. 358/1.9; 358/518; 382/167

(57) ABSTRACT

The present invention is suitable for a computer to (printing) plate to generate specific color accurately, applied data conversion modules included in Profile technique to generate specific color. Drafting software is developed for the pre-print designers adjust CMYK four colors process for printing in allowable proportion to meet the customer's color specification. A tour guide test table composed of 600 colorants is printed out by CMYK color printer, and a subsequent test table constructed by moving colorimeter or spectrophotometer through the colorants, first a forward module constructed by converting CMYK into CIEL*a*b*, and then a reverse module converting CIEL*a*b* into CMYK constructed by optimizing solutions of delta error convergence and error estimates methods. After measuring the CIEL*a*b* values of the specific color by colorimeter, applied the forward and reverse modules to predict CMYK color values in allowable proportion, achieve a better, speedy, and accurate drafting effects.

### FIELD OF THE INVENTION

The present invention relates to computer to plate applied drafting methods to generate specific color accurately, particularly to preprint adjust CMYK four colors process for printing in proportion approach the original color.

### BACKGROUND OF THE INVENTION

Recently, the pre-print designer received the specific color usually accompanied by customers' CMYK color specification. However, the computer to plate (or press) process ink colors of printing usually are device-dependent and the ink colors are distributed unevenly, they may happen to result in cumbersome, erroneous prints. Otherwise, the designer used to compare the specific color with a pre-determined color charts through an accepted-pairing process.

The color chart is to provide the C,M,Y,K four colors (or the three color subtractive primaries, cyan, magenta, yellow plus black) according to a certain proportion of colorants combined to form a persistence of vision color level, all of the color levels described color values at percentage rate (since 0 to 100 percent) to present C,M,Y,K color separation.

By means of color separation, may find the colorant close to the specific color, in that, C,M,Y,K color values are distributed numerically in proportion in a specified system used as a copy model. Though colorants viewed by human observers, each pre-print designer has different feelings for color senses, even if the specific colors were hard to find in the color chart. But the colorants distributed in the C,M,Y,K proportionate measure color charts were named and listed in a series of integral numbers consecutively. The specific color shall be located between the two adjacent numbered colorants, the real C, M, Y, K distributed in proportion was hard to blend to form the required colorants. So the customers used to neglect the printing quality look for excuses for cover up as “sounds like”, while it caused the printing errors, inefficiency and wasted time.

Point against the aforesaid defect, the present invention provides a suitable solution applied CIEL*a*b* international standard accurate algorithm for computer color processing to adapt to the spectrophotometer, may calculate the total color tolerance Delta Error A E accurately and then develop a minimal difference prediction methods of specific color. Thus meets the requirements by growing needs as the customers desired for a look better print quality day by day.

### SUMMARY OF THE INVENTION

While receiving the specific color orders from the customer, the pre-print designers used to spend hours to adjust the software well-regulated C,M,Y,K proportionate measure draw near to the specific color as the customers needed.

The present invention is applied forward module and reverse module in Profile technique, according to the CIEL*a*b* chromaticity values, soon to predict the proportionate measure C,M,Y,K color values accurately. Particularly, the color tolerance Delta Error ΔE, which is proposed by the real specific color compared with the prediction specific color, may draw near to the original specific color provided by the customer

First of all, the present invention intends to generate a color tour guide test table composed of 600 colorants, the colorants included in the tour guide test table are evenly distributed in the scope of high brightness, low brightness, middle tone, high chromatic pathway, low chromatic pathway and achromatic pathway, each colorant defined incremental finite-difference color level, then print out the color tour guide test table through the printer, and then following up the CIEL*a*b* chromaticity (color space) subsequent test table generated by spectrophotometer or colorimeter to convert the CMYK into CIEL*a*b* to form a forward module.

Secondly, to generate mass Look Up Table via the forward module, then optimize solution for the delta error convergence and error estimates standard procedure, final reckoning the hypothetic conversion of CIEL*a*b* into CMYK constructed as a reverse module.

Aforesaid optimizing solution of delta error convergence standard procedure reckoned from finding the minimal color difference among the adjacent numbered colorants and needed to customize specific color. And then through the dichotomy algorithm to lessen the scope of accepted-pairing step by step, until the whole accepted-pairing color difference value is convergent to the minimal limit or approach to zero, finally, to achieve the “needed to customize” colorant close to the specific color as required.

By means of forward and reverse modules, the pre-print designer only need to move colorimeter through a sequence measurement and sample measure the CIEL*a*b* chromaticity values of the specific color, and then to reckon the CMYK proportionate measure by reverse module soon for drafting print color effects accurately and promptly.

### BRIEF DESCRIPTION OF THE DRAWINGS

FIG. 1: A diagram view of the color tour guide test table composed of 600 colorants of the present invention.

FIG. 2: A diagram view of flow chart of a predict method applied Profile technique to simulate the specific color of the present invention.

### DETAILED DESCRIPTION OF THE EMBODIMENTS

Colors correction for the computer to (printing) plate aims to bring a series of data conversion causally related to convert chromaticity coordinate CIEXYZ (calculated from the CIEXYZ tri-stimulus values) into four colors process for printing (CMYK, or three color subtractive primaries plus black). Thus get color adjustment layer to customize the print color so as to approach the designated XYZ or LAB (color space) color value. Related algorithms described in details thereafter.

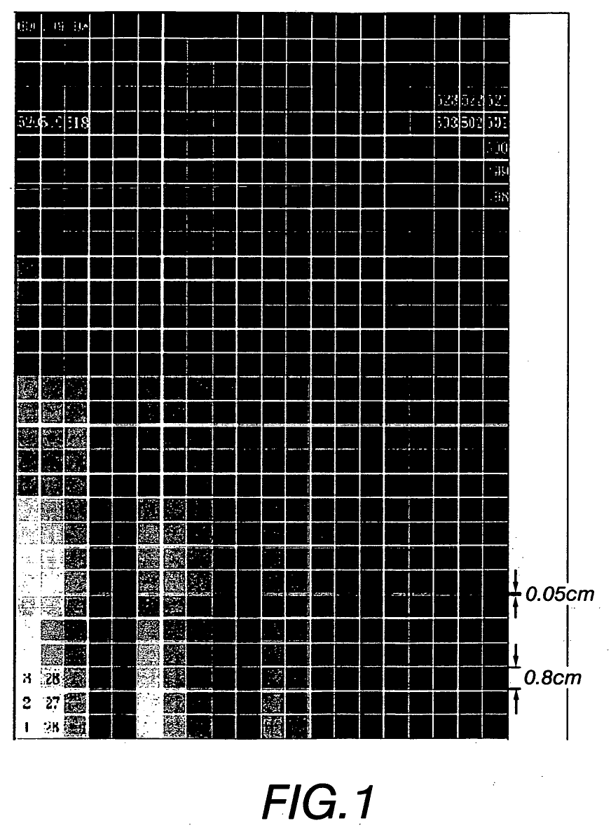

Data conversion casually related to convert CIEL*a*b* into CMYK color values of the printer. Processing data conversion between four colors process for printing of the printer and CIEL*a*b*, first may print out a test image of CMYK composed of 600 colorants, the color values of the colorants are sampled from the CMYK color space of the printer. Those colors are defined by ANSI IT8.73 CMYK standard test color drafts, moreover, sampled by the same as FIG. 1 illustrated.

There are two choices for measuring color drafts: 1. A specific device is applied a color measurement scale or system to measure CIEL*a*b* color value for every possible colorant combination, while measuring colorants usually the light source was set up as Graphic Art D50 regulated. 2. A bitmap conversion of graphic image software such as Photoshop converts the four colors process for printing (CMYK mode) test image into the CIEL*a*b* color mode of Photoshop. According to the CMYK color default setting for printers, Photoshop begins to tell the CIEL*a*b* tri-stimulus color values of every possible colorant combination as soon as the test image arranged in a spool queue for the printer. Those color values may be used to construct the specific file of CMYK four colors process for printing of the printer. But the well-judged results is determined by whether the operation feature of the user's printer default setting is compatible with the Photoshop's default setting or not. Also determined by the conversion data from CMYK into CIEL*a*b* is begun to tell by Photoshop with exactitude.

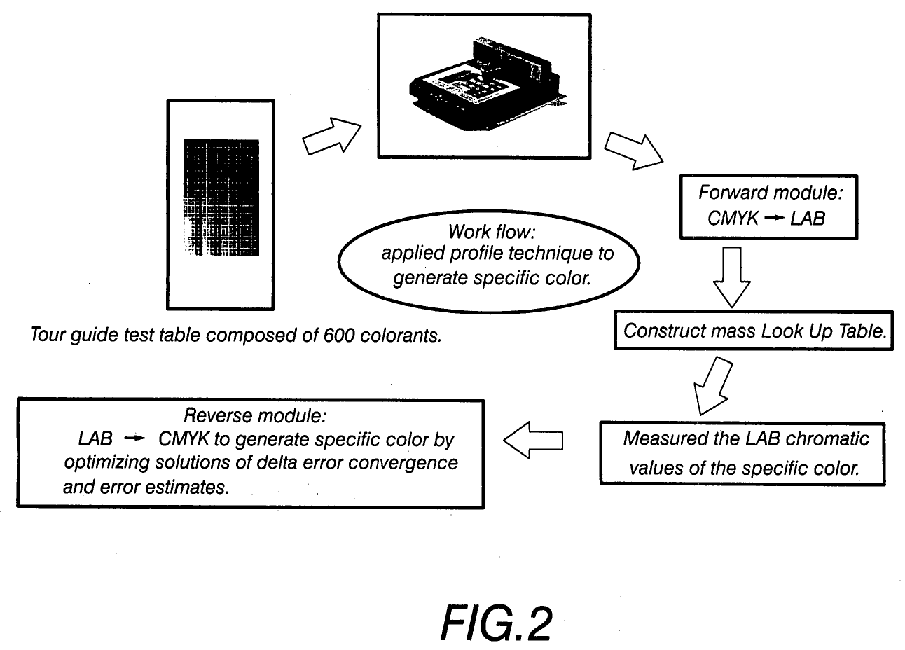

According to the colorants measured data values and what are the CMYK color values corresponding to, data conversion causally related to exchange between CMYK color values of the color printer and CIEL*a*b* can be reckoned from as to construct forward and reverse modules. In that, first convert printer's CMYK into CIEL*a*b* to construct a forward module, and then by optimizing solutions for delta error (color tolerance E) convergence and error estimates to convert CIEL*a*b* into printer's CMYK thus based on the forward module to construct a reverse module as FIG. 2 illustrated.

Forward Module

Forward module of the CMYK printer is, first according to the color values of CMY (three color subtractive primaries) being interpolated eight points distributed in a 3D space drawn twice, then being interpolated between them in a linear manner result from the K (black color) value once, to achieve a user-determined goal. In case of a corresponding CIEL*a*b* color space is reckoned from a certain CMYK printer with cyan, magenta, yellow and black (Ct, Mt, Yt, Kt) color values. First deem the Kt color value may be located between which the two black sampling values are. Supposing that Kt is located between black 1 and black 2 (K1, K2), as K1 for black 1, the test draft includes dissected colorants belong to the CMY (three color subtractive primaries) color space, to spot which color matching palette on the test draft the cyan, magenta and yellow (Ct,Mt,Yt) are located at. Then applied the 8 interpolation points distributed in 3D space methods to spot the CIEL*a*b* color value (L1,a1,b1) corresponding to the black 1, cyan, magenta and yellow color values (K1,Ct,Mt,Yt). The same methods can be applied to spot the CIEL*a*b* color value (L2, a2, b2) corresponding to black 2, cyan, magenta and yellow (K2,Ct,Mt,Yt).

Finally, being based on the (L1,a1,b1) corresponding to black 1, cyan, magenta and yellow (K1,Ct,Mt,Yt) and the (L2,a2,b2) corresponding to black 2, cyan, magenta and yellow (K2,Ct,Mt,Yt) to spot the (Lt,at,bt) corresponding to (Kt,Ct,Mt,Yt). In that, the linear interpolation between them is reckoned from the black 1 (K1), black 2 (K2) and black (Kt). It is a weighing factor as (K2−Kt)/(K2−K1) to multiply the (L1,a1,b1), but (L2,a2,b2) is multiplied by weighing factor (Kt−K1)/(K2−K1).

Reverse Module

Data conversion casually reckon CIEL*a*b* color space from CMYK color values of the color printer, which is based on the aforesaid forward module, and then optimizing solution for error delta (color tolerance E) convergence and error estimates to construct a reverse module.

While CIEL*a*b* values distributed in 3D space may be corresponding to 4 dimensional CMYK color values in different ways such as a gray colorant may simply be used a black color process printing cyan=magenta=yellow=0 (C=M=Y=K), or being used CMY three subtractive color primaries process blend printing black=0 (K=0). In general added an extra conditional conversion setting as Gray Component Replacement technique (abbreviated GCR) defined the only one answerable accepted-pairing. Since every colorant contain more or less gray tones such as red, green and blue (R,G,B)=(255,180,180) may contain gray and red tone-change. As mentioned-above, the gray tone may be printed out by CMY three color subtractive primaries blending for printing or simply by K black color process for printing. In GCR a color separation setting used a GCR ratio to describe this CMY or K values. Thus GCR Ratio means cyan, magenta and yellow inks are swapped out of an image (in a balance that would yield a gray value) and black ink is swapped in instead. And GCR ratio determines a certain gray component are printed out by black ink in the maximum allowable ratio, and the residue gray component are printed out by CMY inks, which is distributed in the allowable ratio as 1—GCR ratio.

What is claimed is:

1. Simulation of profile gives prediction of specific colors comprise the process as following:
(1) Designed a color correction tour guide test table, in that, the CMYK four color (cyan, magenta, yellow and black) inks arranged into the finite-difference color level blended in an incremental manner, the colorants included in the tour guide test table are evenly distributed in the scope of high brightness, low brightness, middle tone, high chromatic pathway, low chromatic pathway and achromatic pathway so as to examine the drafting efficacy of the computer to (printing) plate;
(2) Converted CMYK into CIEL*a*b* to generate forward module Look Up Table, only the color corrected calorimeter or spectrophotometer moved through the print out tour guide test table having the CIEL*a*b* values as corresponding to a data conversion table;
(3) Reckoning a reverse module based on the aforesaid forward module, the data conversion reckoned from 3D CIEL*a*b* to four dimensional values of CMYK are not only one-to-one answerable accepted-pairing, by means of optimizing solution for delta error convergence and error estimates constructed each reverse module conversion.

2. Simulation of profile gives prediction of specific colors of claim 1 wherein the colorimeter measured the tour guide test table, its light source and vision angle setting is compatible with the specific color print out environmental setting.

3. Simulation pf profile gives prediction of specific colors of claim 1 wherein the scope of the predictable specific color includes the color range distributed in the printable scope of the printer.
